(19) United States
(12) Patent Application Publication
(10) Pub. No.: US 2012/0224341 A1
(43) Pub. Date: Sep. 6, 2012

(54) HEIGHT-ADJUSTABLE ELECTROMAGNETIC SHIELDING STRUCTURE

(76) Inventors: Cheng-Her Hsieh, Nantou County (TW); Chao-Ching CHIU, Nantou County (TW)

(21) Appl. No.: 13/091,456

(22) Filed: Apr. 21, 2011

(30) Foreign Application Priority Data
Mar. 3, 2011 (TW) 100107013

(51) Int. Cl. H05K 7/02

(52) U.S. Cl. 361/760

(57) ABSTRACT

A height-adjustable electromagnetic shielding structure is located above an electronic element of a circuit board and includes an electromagnetic screen member, a connecting portion connected to the electromagnetic screen member, and a height stacking member. The height stacking member includes a coupling portion which is formed in a stepped structure and perpendicular to the electromagnetic screen member and circuit board, and contains an upper coupling portion and a lower coupling portion. The upper coupling portion has one end connected to the electromagnetic screen member through the connecting portion and another end connected to the lower coupling portion. At least two height stacking members are stacked over one another through the upper and lower coupling portions to perform height adjustment. The electromagnetic screen member, connecting portion and height stacking member are formed integrally, hence merely one set of mold is needed to reduce the cost.

### FIELD OF THE INVENTION

The present invention relates to an electromagnetic shielding structure and particularly to a height-adjustable electromagnetic shielding structure.

### BACKGROUND OF THE INVENTION

With constant progress and convenience of technology people are eager for, the dimension of electronic elements is shrunk gradually, and sensitivity of input/output signals of the electronic elements also must be enhanced to meet the dimension thereof. In such a condition, interference of external electromagnetic signals to high sensitive electronic elements becomes a serious issue. To address this issue, varying types of shielding structure have been developed and introduced. FIG. 1 illustrates a conventional electromagnetic shielding structure which mainly includes an upper cover 1 and a lower coupling element 2. The lower coupling element 2 is first bonded to an electronic baseboard (not shown in the drawing) by fastening or soldering, then the upper cover 1 is fastened to the lower coupling element 2 by latching or screwing. In the event that redo or rework is needed on the electronic element, the upper cover 1 is opened to perform necessary rework, then the upper cover 1 is covered again. Such a design provides reuse possible and makes mass production simpler, but it requires two sets of molds for production, hence the cost is higher. Moreover, at the beginning of product development, tests have to be performed for electromagnetic shielding structures with different heights. After the optimal setting is determined by testing, modeling molds for mass production can be performed. However, electromagnetic shielding structures with different heights need varying sets of molds with different heights to meet requirements, thus additional costs are increased.

### SUMMARY OF THE INVENTION

Therefore, the primary object of the present invention is to solve the problem of the conventional technique that needs to model multiple sets of molds with varying heights to fabricate different electromagnetic shielding structures.

To achieve the foregoing object, the present invention provides a height-adjustable electromagnetic shielding structure which is located above at least one electronic element of a circuit board to prevent the electronic element from receiving electromagnetic interference. The electromagnetic shielding structure includes an electromagnetic screen member, a connecting portion connected to the electromagnetic screen member, and a height stacking member. The electromagnetic screen member is located at one side of the electronic element far from the circuit board to fully cover the electronic element. The height stacking member includes a coupling portion which is formed in a stepped structure and contains an upper coupling portion and a lower coupling portion. The upper coupling portion has one end connected to the electromagnetic screen member through the connecting portion and another end connected to the lower coupling portion. The coupling portion is perpendicular to the electromagnetic screen member and circuit board. The connecting portion can be severed to separate the electromagnetic screen member and the height stacking member. A plurality of height stacking members can be stacked over one another to adjust the height of the electromagnetic shielding structure.

By means of the aforesaid structure, the height stacking members can be stacked over one another through the stepped coupling portions, and the connecting portion can be severed to separate the height stacking member and the electromagnetic screen member, hence only the electromagnetic screen member at the upmost layer remains to achieve height adjustment purpose of the electromagnetic shielding structure. Through the invention, only one set of mold is required to fabricate the electromagnetic shielding structure with the same type, and height can be adjusted as desired. As a result, mold developing and modeling costs can be reduced to lower total cost.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of a conventional technique.

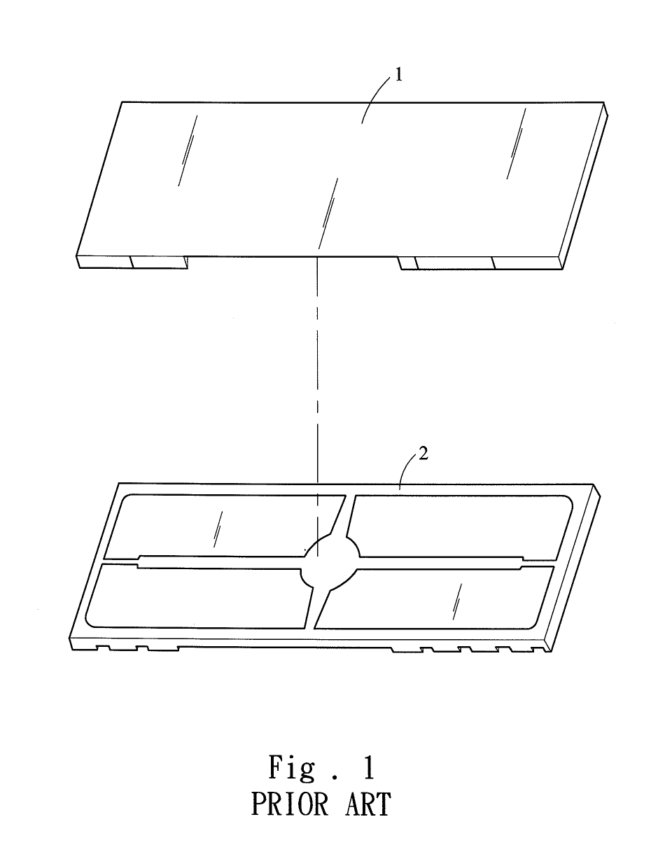

FIG. 2 is a perspective view of an embodiment of the invention.

FIG. 3 is an exploded view of an embodiment of the invention.

FIG. 4 is a fragmentary enlarged view of an embodiment of the invention.

### DETAILED DESCRIPTION OF THE PREFERRED EMBODIMENT

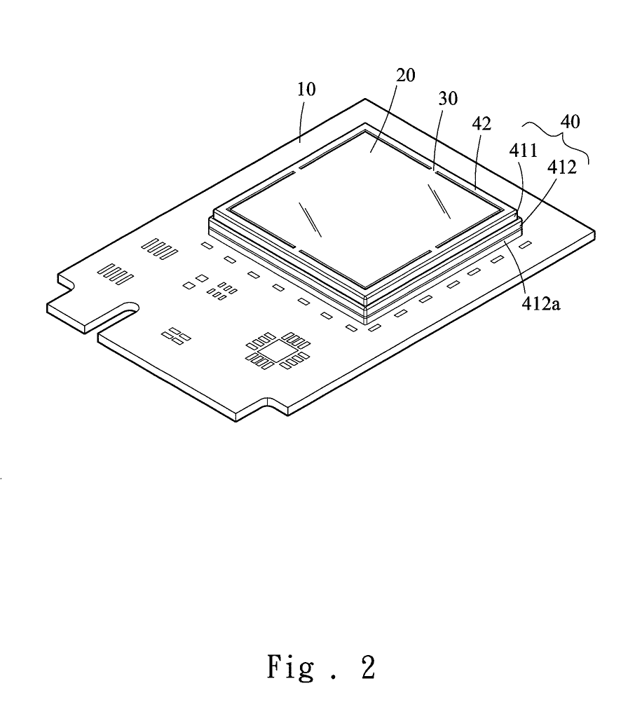

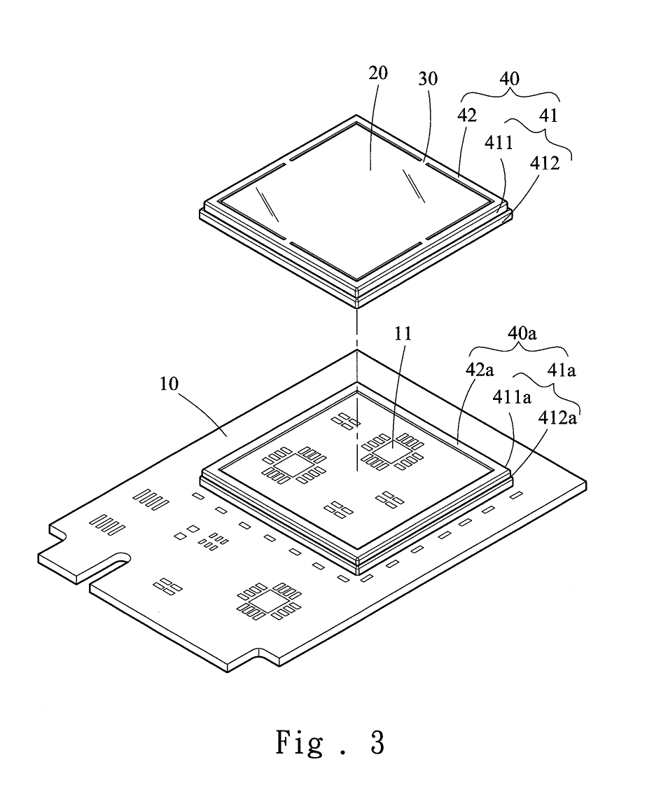

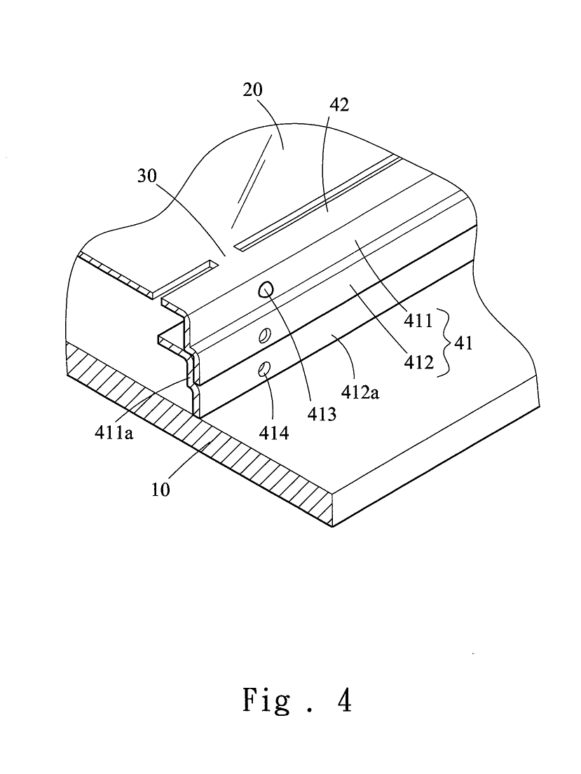

Please refer to FIGS. 2 through 4 for an embodiment of the height-adjustable electromagnetic shielding structure of the invention. The height-adjustable electromagnetic shielding structure of the invention is located above at least one electronic element 11 of a circuit board 10 to prevent the electronic element 11 from receiving electromagnetic interference. The electromagnetic shielding structure includes an electromagnetic screen member 20, a connecting portion 30 connected to the electromagnetic screen member 20, and a height stacking member 40. The electromagnetic screen member 20 is located at one side of the electronic element 11 far from the circuit board 10 to fully cover the electronic element 11. In this embodiment, the connecting portion 30 includes multiple sets located on the periphery of the electromagnetic screen member 20 and connected to the height stacking member 40 to form firmer connection effect. The height stacking member 40 includes a coupling portion 41 which is formed in a stepped structure and includes an upper coupling portion 411 and a lower coupling portion 412. The upper coupling portion 411 has one end connected to the electromagnetic screen member 20 through the connecting portion 30 and another end connected to the lower coupling portion 412. The coupling portion 41 is perpendicular to the electromagnetic screen member 20 and circuit board 10. The connecting portion 30 can be severed to separate the electromagnetic screen member 20 and the height stacking member 40. The connecting portion 30 can be severed by bending or shearing for separation. A plurality of height stacking members 40 and 40a can be provided and stacked over one another to adjust the height. In this embodiment, the electromagnetic screen member 20, connecting portion 30 and height stacking members 40 and 40a are respectively made of metal, thus have slight resilience for adjustment and also have capability to shield electromagnetic waves. Moreover, the connecting portion 30 and height stacking member 40 are extended from the electromagnetic screen member 20. Hence the electromagnetic shielding structure of the invention can provide height adjustment and convenient opening functions through merely modeling one set of mold.

More specifically, multiple sets of the height stacking members 40 and 40a can be stacked over one another with an inner side of the lower coupling portion 412 of the height stacking member 40 far from the circuit board 10 to clamp an outer side of the upper coupling portion 411a of the height stacking member 40a adjacent to the circuit board 10 to form stacking. The height stacking members 40 and 40a respectively has an elastic clamping portion 42 and 42a. Take the height stacking member 40 far from the circuit board 10 for an example, the elastic clamping portion 42 is located between the connecting portion 30 and coupling portion 41. When multiple height stacking members 40 and 40a are stacked over one another, the inner side of the lower coupling portion 412 of the height stacking member 40 far from the circuit board 10 clamps the outer side of the upper coupling portion 411a of the height stacking member 40a adjacent to the circuit board 10 to form firmer connection effect through elastic expansion. The upper coupling portions 411 and 411a have respectively at least one first fastening element 413, and the lower coupling portions 412 and 412a have respectively at least one second fastening element 414 corresponding to the first fastening element 413. When the height stacking members 40 and 40a are stacked over one another, the first and second fastening elements 413 and 414 couple with each other for fastening to prevent the height stacking members 40 and 40a from slipping. In this embodiment, the first fastening element 413 is a boss while the second fastening element 414 is a mating circular hole to form fastening as desired. Of course, the first fastening element 413 may also be a circular hole while the second fastening element 414 is a mating boss. Moreover, multiple sets of first and second fastening elements 413 and 414 may also be provided on the periphery of the height stacking members 40 and 40a as required.

When the invention is in use, first, directly cover the electromagnetic shielding structure of the invention on one side of the electronic element 11 of the circuit board 10; and connect the lower coupling portion 412a to a ground pad (not shown in the drawings) on the surface of the circuit board 10 to form electrical connection and further form a shielding structure. In the event that rework or redo is required on the circuit board 10, bend or sever the connecting portion 30 to separate the electromagnetic screen member 20 (removed, not shown in the drawings), then perform rework on the circuit board 10; stack a new electromagnetic shielding structure on the height stacking member 40a and clamp the coupling portions 41 and 41a to form coupling and fastening to achieve electromagnetic shielding function again. In the event that more rework is needed, pull away the electromagnetic shielding structure at the upper layer to perform rework operation continuously. In the event that the electronic element 11 is formed at a height greater than the electromagnetic shielding structure, multiple height stacking members 40 can be stacked to increase the height thereof until reaching a height as desired, therefore height adjustment can be achieved.

As a conclusion, the invention can be stacked through the stepped coupling portions 41 of the height stacking members 40, and separate the height stacking member 40 from the electromagnetic screen member 20 through the connecting portion 30, thus can keep merely the electromagnetic screen member 20 at the upmost layer during stacking to adjust the height of the electromagnetic shielding structure. Moreover, the invention needs only one set of mold to fabricate the same type of the electromagnetic shielding structure to achieve height adjustment function. Thus mold development cost can be saved and production cost can also be reduced.

While the invention has been described by means of specific embodiments, numerous modifications and variations could be made thereto by those skilled in the art without departing from the scope and spirit of the invention set forth in the claims.

In summation of the above description, the present invention provides a significant improvement over the conventional techniques and complies with the patent application requirements, and is submitted for review and granting of the commensurate patent rights.

What is claimed is:

1. A height-adjustable electromagnetic shielding structure located above at least one electronic element of a circuit board to prevent the electronic element from receiving electromagnetic interference, comprising:
an electromagnetic screen member located at one side of the electronic element far from the circuit board to fully cover the electronic element;
a connecting portion connected to the electromagnetic screen member; and
a height stacking member which is located on the periphery of the electromagnetic screen member and includes a coupling portion formed in a stepped structure and including an upper coupling portion and a lower coupling portion and perpendicular to the electromagnetic screen member and the circuit board, the upper coupling portion including one end connected to the electromagnetic screen member through the connecting portion and anther end connected to the lower coupling portion.

2. The height-adjustable electromagnetic shielding structure of claim 1, wherein the height stacking member includes an elastic clamping portion interposed between the connecting portion and the coupling portion.

3. The height-adjustable electromagnetic shielding structure of claim 2, wherein the height stacking member includes multiple sets stacked over one another, the lower coupling portion far from the circuit board including an inner side clamping an outer side of the upper coupling portion of another height stacking member adjacent to the circuit board to form stacking.

4. The height-adjustable electromagnetic shielding structure of claim 3, wherein the upper coupling portion includes at least one first fastening element and the lower coupling portion includes at least one second fastening element corresponding to the first fastening element, the first fastening element and the second fastening element being coupled with each other for fastening to prevent the height stacking members from slipping during stacking.

5. The height-adjustable electromagnetic shielding structure of claim 4, wherein the first fastening element is a boss and the second fastening element is a circular hole.

6. The height-adjustable electromagnetic shielding structure of claim 4, wherein the first fastening element is a circular hole and the second fastening element is a boss.

7. The height-adjustable electromagnetic shielding structure of claim 1, wherein the connecting portion and the height stacking member are extended from the electromagnetic screen member.

8. The height-adjustable electromagnetic shielding structure of claim 1, wherein the connecting portion includes multiple sets located on the periphery of the electromagnetic screen member and connected to the height stacking member.

9. The height-adjustable electromagnetic shielding structure of claim 1, wherein the electromagnetic screen member, the connecting portion and the height stacking member are respectively made of metal.
